(19) United States
(12) Patent Application Publication
(10) Pub. No.: US 2026/0371918 A1
(43) Pub. Date: Nov. 19, 2026

(54) PEROVSKITE PRECURSOR SOLUTION, PEROVSKITE SOLAR CELL AND PREPARATION METHOD THEREFOR, AND PHOTOVOLTAIC SYSTEM

(71) Applicant: SHENZHEN PHENOSOLAR TECHNOLOGY CO., LTD., Shenzhen, Guangdong (CN)

(72) Inventor: Tianhao YAN, Shenzhen (CN)

(21) Appl. No.: 18/995,573

(22) PCT Filed: Aug. 6, 2024
(86) PCT No.: PCT/CN2024/110188

§ 371 Date: Jan. 16, 2025

(30) Foreign Application Priority Data
Jun. 8, 2023 (CN) 202310673659.2

(51) Int. Cl. H10K 85/60; C09D 5/24; C09D 7/63; H10K 30/40

(52) U.S. Cl. CPC H10K 85/631; C09D 5/24; C09D 7/63; H10K 30/40

(57) ABSTRACT

The present disclosure relates to a perovskite precursor solution, a perovskite solar cell and a preparation method thereof, and a photovoltaic system. The perovskite precursor solution includes a perovskite material and a transport functional material having a structure shown in Formula I, where A represents an electron acceptor, D represents an electron donor, X represents a donor group, and Y represents an acceptor group. The structure of the transport functional material includes an electron donor and an electron acceptor, which can transport electrons or holes. The perovskite precursor solution is adopted in preparing a perovskite solar cell, and can form a perovskite layer and a first transport layer between the perovskite layer and a transparent electrode in one step, addressing the coating issue caused by wettability between functional layers in step-by-step preparation, while avoiding the issues of non-radiative recombination and increase in defects caused by multi-step preparation.

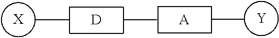

### CROSS-REFERENCE TO RELATED APPLICATIONS

This application is an U.S. national phase application under 35 U.S.C. § 371 based upon international patent application No. PCT/CN2024/110188, filed on Aug. 6, 2024, which itself claims priority to Chinese patent application No. 202310673659.2, filed on Jun. 8, 2023, entitled “PEROVSKITE PRECURSOR SOLUTION, PEROVSKITE SOLAR CELL AND PREPARATION METHOD THEREOF, AND PHOTOVOLTAIC SYSTEM”. The contents of the above identified applications are hereby incorporated herein in their entireties by reference.

### TECHNICAL FIELD

The present disclosure relates to the technical field of solar cells, in particular to a perovskite precursor solution, a perovskite solar cell and a preparation method thereof, and a photovoltaic system.

### BACKGROUND

As the third generation of photovoltaic cell technology, perovskite solar cells have been rapidly developed, with the laboratory-certified energy conversion efficiency increased from 3.8% to 25.8%, which were comparable with mature monocrystalline silicon solar cells. Perovskites can be used to prepare photovoltaic devices through solution processing techniques, such as spin-coating and printing. Compared with the techniques for manufacturing silicon-based photovoltaics, the solution processing offers a more cost-effective approach for larger scale production. Perovskite materials refer to a class of ceramic oxides represented by a molecular formula ABX₃. These materials can be well applied to photovoltaic devices, luminescent displays, photoelectric detection, optical communications, and other fields.

Slot-die coating has been commonly used in the mass production of conventional perovskite film cells, and is the most successful process for obtaining uniform functional layers and perovskite films. With respect to the coating, in addition to the stability and repeatability of the coating machine itself, the material properties of substrates also determine the quality of the coating films and the performance of the solar cells. Moreover, the interface between the perovskite layer and the transport layer is the place that is most likely to produce non-radiative recombination, resulting in perovskite crystal defects at the interface. Therefore, how to coat high-quality films more easily while reducing non-radiative recombination at the interface is the key to further improving the performances of perovskite solar cells.

### SUMMARY

In view of this, the present disclosure provides a perovskite precursor solution that can form a transport layer and a perovskite layer in one step, avoiding the increase in defects caused by the conventional method for preparing the transport layer and the perovskite layer in separate steps on the substrate.

An aspect of the present disclosure provides a perovskite precursor solution including a perovskite material and a transport functional material. The transport functional material has a structure shown in Formula I:

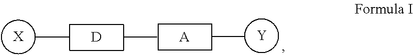

where A represents an electron acceptor, D represents an electron donor, X represents a donor group, and Y represents an acceptor group.

In some embodiments, A is selected from the group consisting of

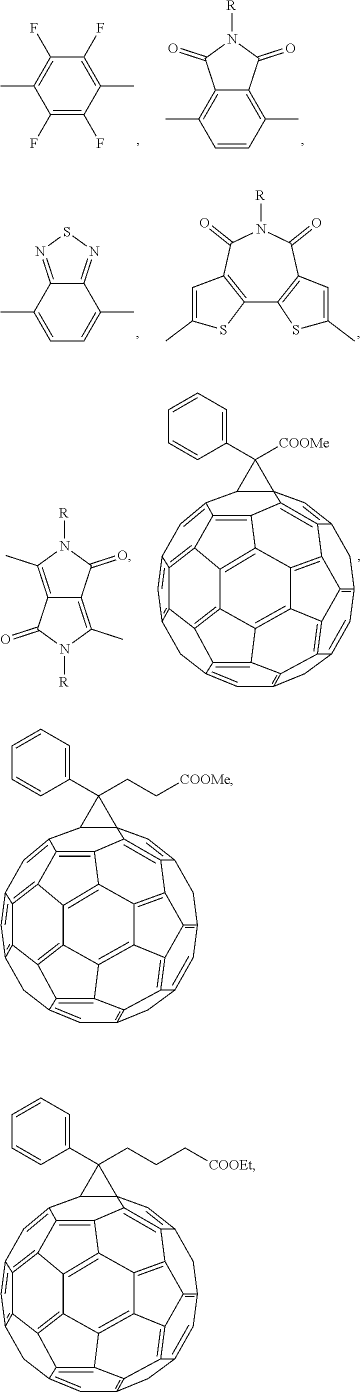

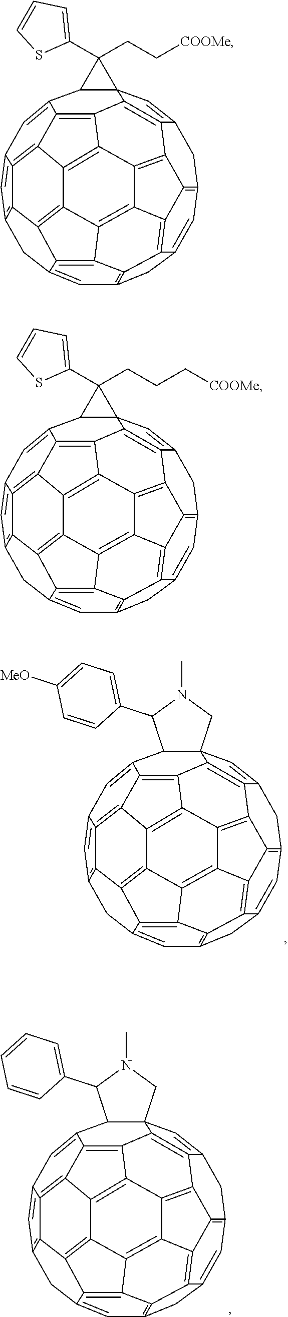 [SMILES: COC(=O)CCC1(c2cccs2)C2c3cc4cc5c6c4c4c3c3c7c8c9c%10c(cc%11c%12c%13c(cc(c%14c%13c%13c(c%12%10)c9c3c4c%13c6%14)C5)C%11)CC8=CC721 ; COC(=O)CCCC1(c2cccs2)C2c3cc4cc5c6c4c4c3c3c7c8c9c%10c(cc%11c%12c%13c(cc(c%14c%13c%13c(c%12%10)c9c3c4c%13c6%14)C5)C%11)CC8=CC721 ; COc1ccc(C2C3c4cc5cc6c7c5c5c4c4c8c9c%10c%11c(cc%12c%13c%14c(cc(c%15c%14c%14c(c%13%11)c%10c4c5c%14c7%15)C6)C%12)CC9=CC83CN2C)cc1 ; CN1CC23C=C4Cc5cc6c7c8c(cc9c%10c8c8c%11c7c5c5c4c2c2c4c(cc7cc(c%12c7c4c(c2c5%11)c8c%12%10)C9)C3C1c1ccccc1)C6]

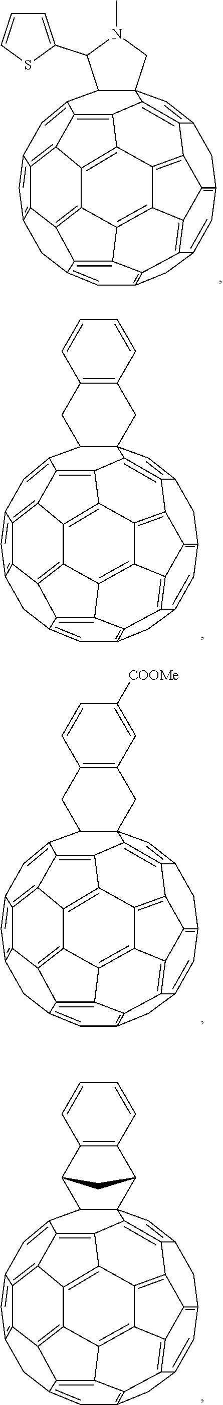

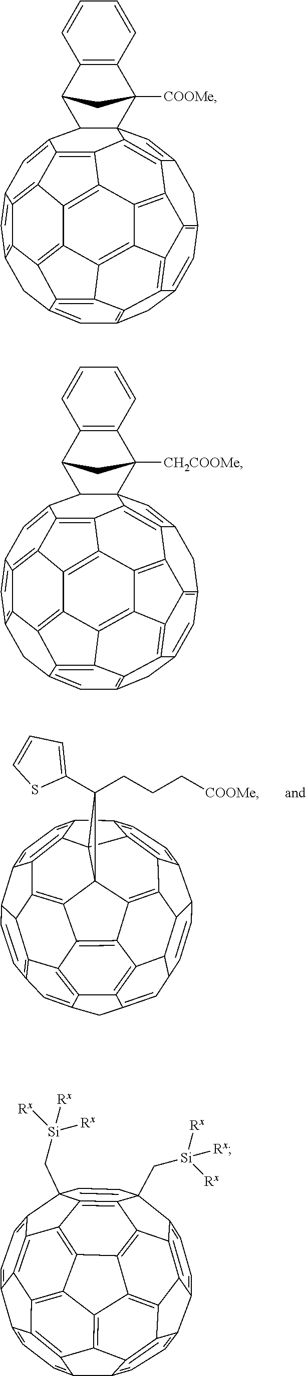

D is selected from the group consisting of

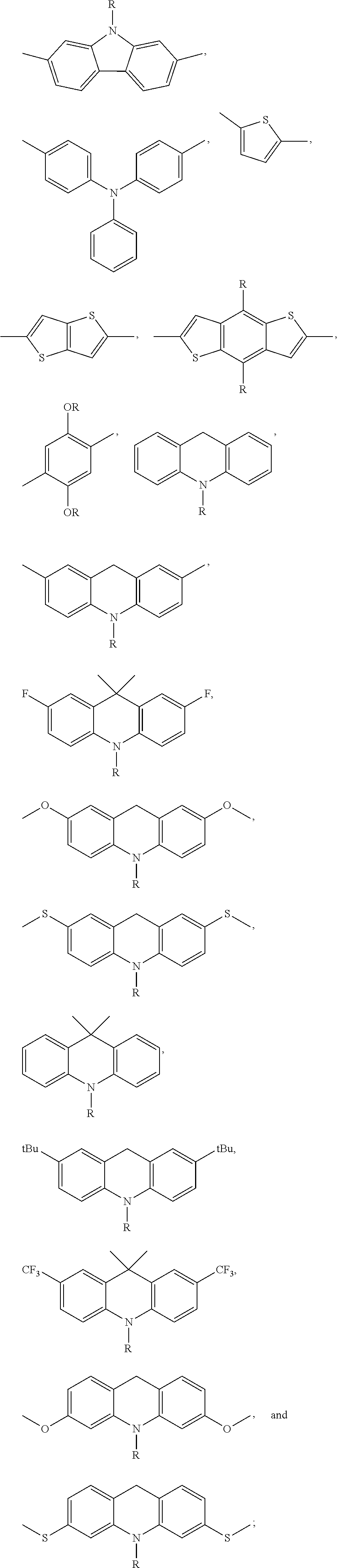

X is selected from the group consisting of

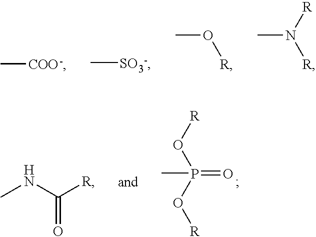

Y is selected from the group consisting of

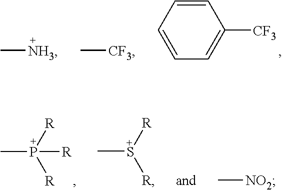

wherein R and R^{X} are each independently selected from the group consisting of linear alkyl, branched alkyl, and cyclic alkyl each having 2 to 40 carbon atoms, where one or more non-adjacent carbon atoms are optionally substituted by —O—, —S—, —C(O)—, —C(O—)—O—, —O—C(O)—, —O—C(O)—O—, —CR⁰═CR⁰⁰—, or —C═C—, and one or more hydrogen atoms can be substituted by F, Cl, Br, I, or CN; or R and R^{X} each independently represent aryl, heteroaryl, aryloxy, heteroaryloxy, arylcarbonyl, heteroarylcarbonyl, arylcarbonyloxy, heteroarylcarbonyloxy, aryloxycarbonyl or heteroaryloxycarbonyl, each having 4 to 30 ring atoms unsubstituted or substituted by one or more non-aromatic groups; wherein R⁰ and R⁰⁰ are each independently linear alkyl, branched alkyl, or cyclic alkyl.

In some embodiments, the transport functional material is selected from the group consisting of

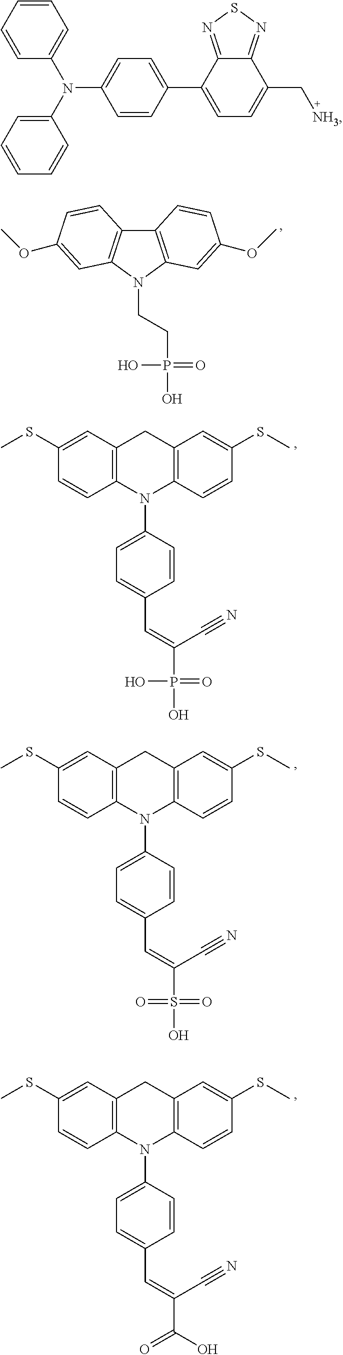

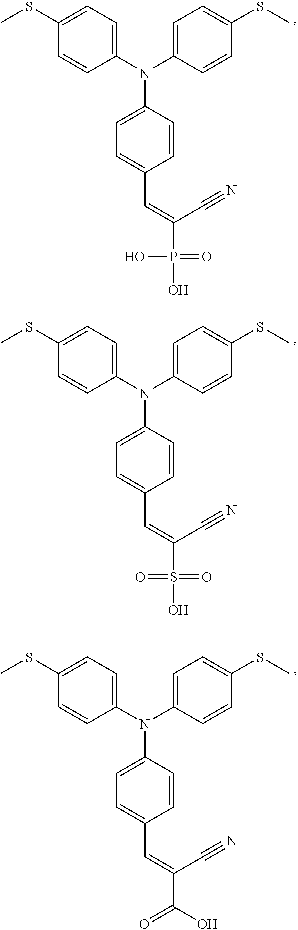

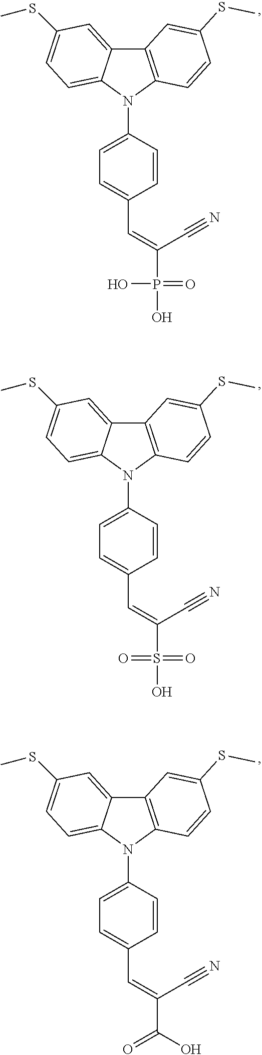

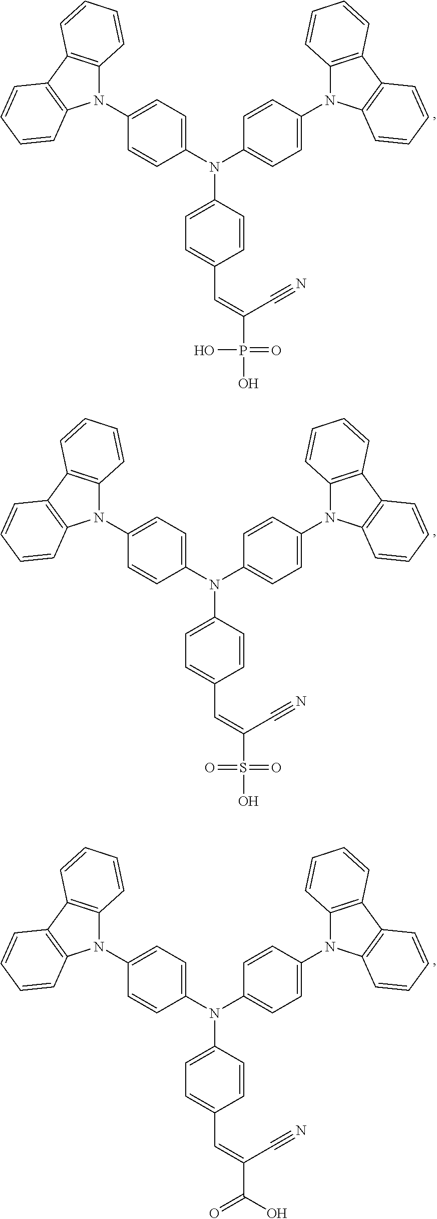

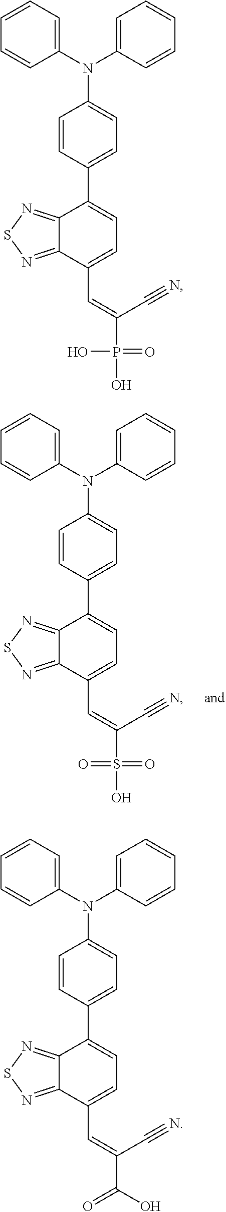

In some embodiments, the transport functional material is

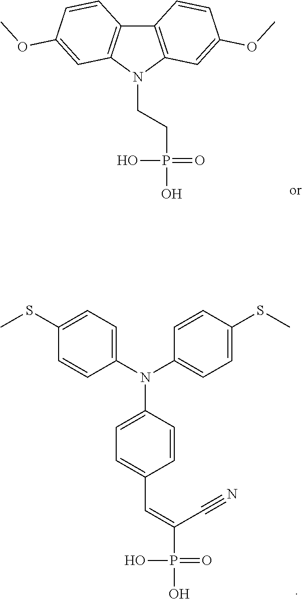

In some embodiments, the perovskite material includes a perovskite-type metal halide represented by a general formula of ABX₃, where A is a monovalent cation, B is a divalent cation, and X is a monovalent anion.

A second aspect of the present disclosure provides a method for preparing a perovskite solar cell, wherein the perovskite solar cell includes a transparent electrode, a first transport layer, a perovskite layer, a second transport layer, and a metal electrode that are stacked.

The method for preparing the perovskite solar cell includes steps of:
coating the perovskite precursor solution as described above on a surface of the transparent electrode to obtain a wet film;
removing a solvent from the wet film to obtain a dry film; and
subjecting the dry film to annealing treatment to obtain the first transport layer and the perovskite layer.

In some embodiments, the coating is slot-die coating, blade coating, or printing. Optionally, the coating is slot coating.

In some embodiments, the method for preparing the perovskite solar cell further includes:
preparing the second transport layer on a surface of the perovskite layer; and
preparing the metal electrode on a surface of the second transport layer.

A third aspect of the present disclosure provides a perovskite solar cell prepared by the method for preparing the perovskite solar cell as described above.

A fourth aspect of the present disclosure provides a photovoltaic system including the perovskite solar cell as described above.

The perovskite precursor solution provided by the embodiments of the present disclosure includes a perovskite material and a transport functional material. The structure of the transport functional material includes an electron donor and an electron acceptor, which can transport electrons or holes. The above-described perovskite precursor solution is adopted in preparing a perovskite solar cell, and can form a perovskite layer and a first transport layer between the perovskite layer and a transparent electrode in one step, addressing the coating issue caused by wettability between functional layers in step-by-step preparation, while avoiding the issues of non-radiative recombination and increase in defects caused by multi-step preparation.

### BRIEF DESCRIPTION OF THE DRAWINGS

FIG. 1 is a schematic structural view of a perovskite solar cell according to an embodiment of the present disclosure.

FIG. 2 shows a J-V curve of a perovskite solar cell prepared in Comparative Example 1 of the present disclosure, in which the horizontal axis represents a voltage and the vertical axis represent a current density.

FIG. 3 shows a J-V curve of a perovskite solar cell prepared in Example 1 of the present disclosure, in which the horizontal axis represents a voltage and the vertical axis represent a current density.

### EXPLANATION OF REFERENCE SIGNS

1: perovskite solar cell; 10: transparent electrode; 20: first transport layer; 30: perovskite layer; 40: second transport layer; 50: metal electrode,

### DETAILED DESCRIPTION

To facilitate understanding of the present disclosure, it will be described below more comprehensively in conjunction with the relevant accompanying drawings. Some embodiments of the present disclosure are given in the drawings. However, the present disclosure can be implemented in many different forms and is not limited to the embodiments described herein. Rather, these embodiments are provided to make the contents disclosed herein more fully understood.

Unless otherwise stated or there is a contradiction, terms or phrases used herein have the following meanings.

In the present disclosure, the terms “and/or”, “or/and”, and “as well as/or” mean that any one of two or more related listed items can be selected, and any or all combinations of the related listed items can be selected. The any or all combinations include the combinations of any two of the related listed items, the combinations of any more of the related listed items, or the combinations of all the related listed items. It should be understood that, when at least three items are connected by a combination of at least two conjunctions selected from “and/or”, “or/and”, and “as well as/or”, the technical solutions undoubtedly include technical solutions that are all connected by “logical AND” and also undoubtedly include technical solutions that are all connected by “logical OR”. For example, “A and/or B” includes three parallel solutions, i.e., A, B, and a combination of A and B. Alternatively, for example, the technical solutions of “A and/or B and/or C and/or D” include any one of A, B, C, and D (i.e., the technical solutions connected by “logical OR”), as well as any or all combinations of A, B, C, and D, that is, including the combinations of any two or three of A, B, C, and D, and also including the combination of A, B, C, and D (i.e., the technical solutions connected by “logical AND”).

In the present disclosure, the terms “a plurality of”, “multiple”, “many times”, “plural”, and the like, refer to a number equal to or greater than 2, unless otherwise specified. For example, “one or more” means one, or equal to or greater than two.

In the present disclosure, the terms “a combination thereof”, “any combination thereof”, “any combination manner thereof”, and the like, include all suitable combinations of any two or more of the listed items.

In the present disclosure, “suitable” in the terms such as “suitable combination manner”, “suitable manner”, and “any suitable manner”, is defined as being capable of implementing the technical solutions as described in the present disclosure, solving the technical problems as described in the present disclosure, and realizing the expected technical effects as described in the present disclosure.

In the present disclosure, the terms “preferably”, “better”, “preferred” and “appropriate” are only used to describe embodiments or examples with better effects, and it should be understood that, they do not constitute a limitation on the protection scope of the present disclosure.

In the present disclosure, “further”, “furthermore”, “specially”, etc., are used for descriptive purposes, indicating the differences in content, but cannot be understood as a limitation on the protection scope of the present disclosure.

In the present disclosure, “optionally”, “optional”, and “option” mean non-mandatory, indicating two parallel solutions with or without the optional feature. If there is more than one “option” in a same technical solution, unless otherwise specified or there is a contradiction or mutual restriction, each “option” is independent from the others.

In the present disclosure, the terms “first”, “second”, “third”, “fourth”, etc., in “first aspect”, “second aspect”, “third aspect”, “fourth aspect”, etc., are used for descriptive purposes only and are not to be construed as indicating or implying relative importance or quantity, or as implicitly specifying the importance or quantity of the technical features indicated. Moreover, “first”, “second”, “third”, “fourth” and the like only serve the purpose of non-exhaustive enumeration, and it should be understood that they do not constitute a closed-ended limitation on the quantity.

In the present disclosure, an open-ended description for the technical features includes not only a close-ended technical solution consisting of the recited technical features, but also an open-ended technical solution including the recited technical features.

In the present disclosure, unless otherwise specified, when a numerical interval (i.e., a numerical range) is referred to, the suitable values are considered as continuously distributed within this numerical interval and include both endpoints of the numerical interval (i.e., the minimum value and the maximum value), as well as every value between the two endpoints. Unless otherwise specified, when a numerical interval is referred to as encompassing only integers within the numerical interval, it includes the integers at both endpoints of the numerical interval, and every integer between the endpoints, being equivalent to directly listing each integer herein. For example, the phrase “t is an integer ranged from 1 to 10” indicates that t is any integer selected from the integer group consisting of 1, 2, 3, 4, 5, 6, 7, 8, 9, and 10. In addition, when multiple ranges are provided to describe a feature or a characteristic, these ranges can be combined. In other words, ranges disclosed herein should be construed to include any or all sub-ranges subsumed therein, unless otherwise specified.

In the present disclosure, when a temperature parameter is mentioned, unless otherwise specifically stated, not only a thermostatic process but also a variation within a certain temperature interval is allowed. The thermostatic process allows for temperature fluctuations within the accuracy range of the instrument, such as fluctuation within the range of ±5 °C, ±4 °C, ±3 °C, ±2 °C and ±1 °C.

In the present disclosure, when an amount in percentage is mentioned, unless otherwise specifically stated, it refers to mass percentage for both a solid-liquid mixture and a solid-solid mixture, and refers to volume percentage for a liquid-liquid mixture.

In the present disclosure, when a concentration in percentage is mentioned, unless otherwise specifically stated, it always refers to the final concentration, referring to the proportion of the added component in a system after adding that component.

In the present disclosure, “% (w/w)” and “wt %” each mean percentage by weight, and “% (v/v)” means percentage by volume.

The fill factor (FF) used herein refers to the ratio of the actual maximum obtainable power (Pₘ or Vₘₚ×Jₘₚ) to the theoretical (rather than actually obtainable) power (J_{sc}×V_{oc}). Therefore, the FF can be determined by the following formula:

FF=(VₘₚλJₘₚ)/(J_{sc}×V_{oc})

where Jₘₚ and Vₘₚ respectively represent the current density and voltage at the maximum power point (Pₘ), which is obtained by varying the resistance in the circuit until J×V reaches the maximum value. J_{sc} and V_{oc} respectively represent short-circuit current and open-circuit voltage. The fill factor is a key parameter for evaluating solar cells. The fill factor of a commercial solar cell is typically equal to or greater than about 60%.

The open-circuit voltage (V_{oc}) used herein is the electrical potential difference between the anode and the cathode of the device when disconnected from an external load. The power conversion efficiency (PCE) of a solar cell used herein refers to the percentage of power converted from absorbed light to electrical energy. The power conversion efficiency (PCE) of the solar cell can be calculated by dividing the incident light irradiance (E in W/m²) and the surface area (A_{c} in m²) of the solar cell by the maximum power point (Pₘ) under the standard test conditions (STC). STC generally refers to a spectrum at a temperature of 25 °C, an irradiance of 1000 W/m², and an air mass of 1.5 (AM1.5).

An embodiment of the present disclosure provides a perovskite precursor solution including a perovskite material and a transport functional material. The transport functional material has a structure shown in Formula I:

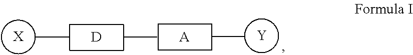

where A represents an electron acceptor, D represents an electron donor, X represents a donor group, and Y represents an acceptor group.

The above-described perovskite precursor solution includes a perovskite material and a transport functional material. The structure of the transport functional material includes an electron donor and an electron acceptor, which can transport electrons or holes. The above-described perovskite precursor solution is adopted in preparing a perovskite solar cell, and can form a perovskite layer and a first transport layer between the perovskite layer and a transparent electrode in one step, addressing the coating issue caused by wettability effects between functional layers in step-by-step preparation, while avoiding the issues of non-radiative recombination and increase in defects caused by multi-step preparation.

In some embodiments, A is selected from the group consisting of

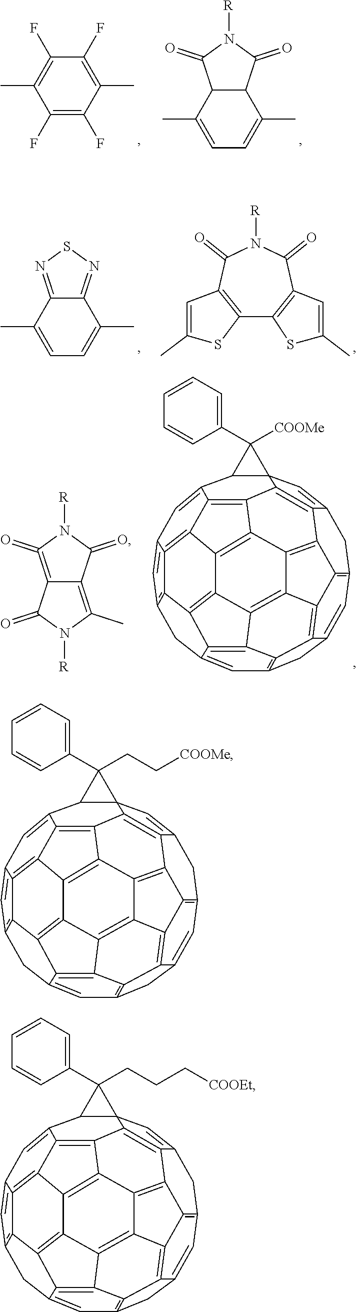

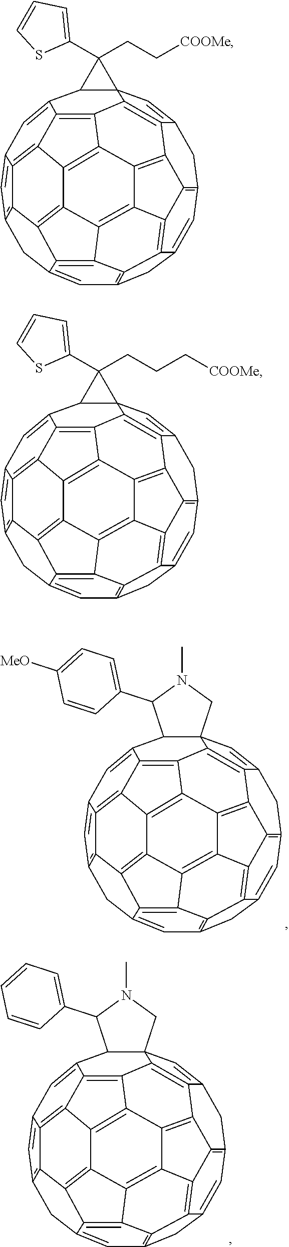

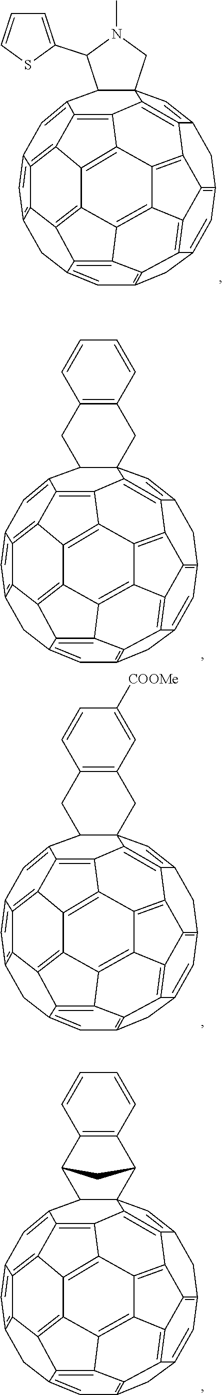

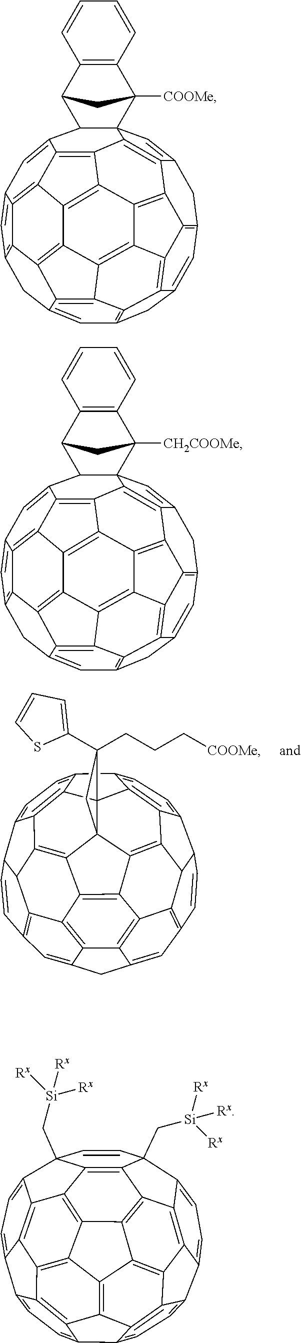

In some embodiments, D is selected from the group consisting of

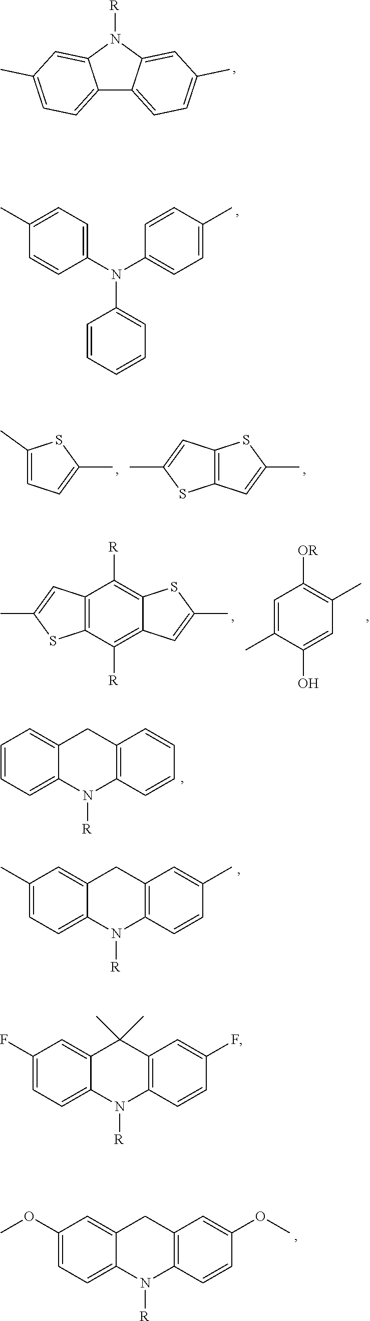

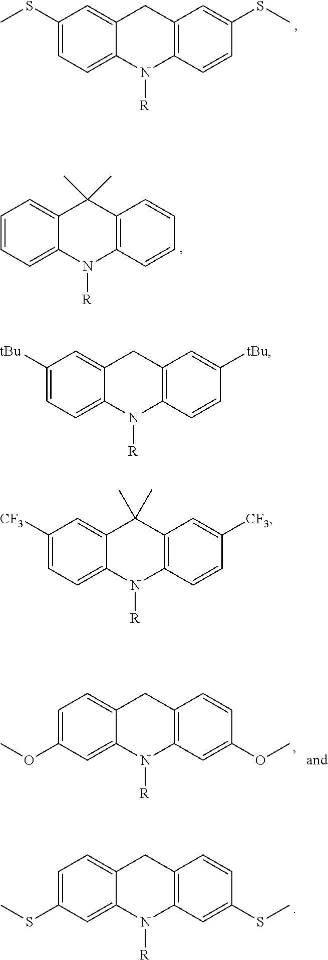

In some embodiment, X is selected from the group consisting of

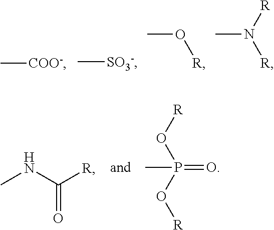

In some embodiment, Y is selected from the group consisting of

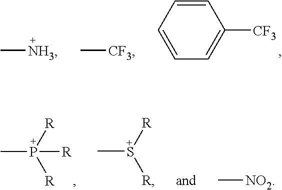

R and R^{X} are each independently selected from the group consisting of linear alkyl, branched alkyl and cyclic alkyl each having 2 to 40 carbon atoms, where one or more non-adjacent carbon atoms are optionally substituted by —O—, —S—, —C(O)—, —C(O—)—O—, —O—C(O)—, —O—C(O)—O—, —CR⁰═CR⁰⁰, or —C═C—, and one or more hydrogen atoms can be substituted by F, Cl, Br, I, or CN; or R and R^{X} each independently represent aryl, heteroaryl, aryloxy, heteroaryloxy, arylcarbonyl, heteroarylcarbonyl, arylcarbonyloxy, heteroarylcarbonyloxy, aryloxycarbonyl or heteroaryloxycarbonyl, each having 4 to 30 ring atoms unsubstituted or substituted by one or more non-aromatic groups; wherein R⁰ and R⁰⁰ are each independently linear alkyl, branched alkyl, or cyclic alkyl.

A and D are connected through a carbon-carbon single bond.

The transport functional material with the above structure not only has an enhanced transport performance, but also can improve the wettability between the perovskite precursor solution and the substrate material.

In some embodiments, the transport functional material is selected from the group consisting of the compounds represented by Formula 1-1 to Formula 1-17.

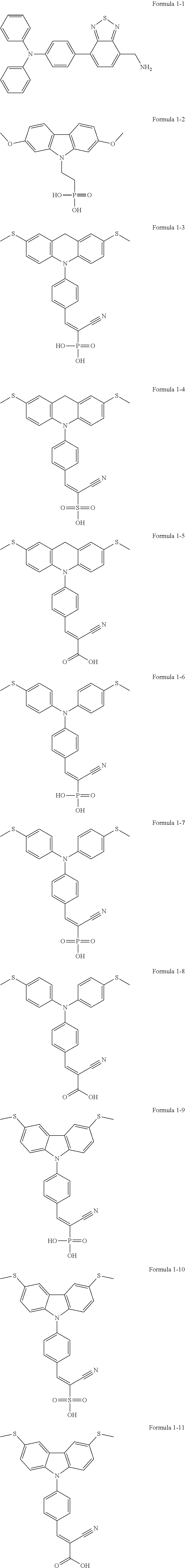

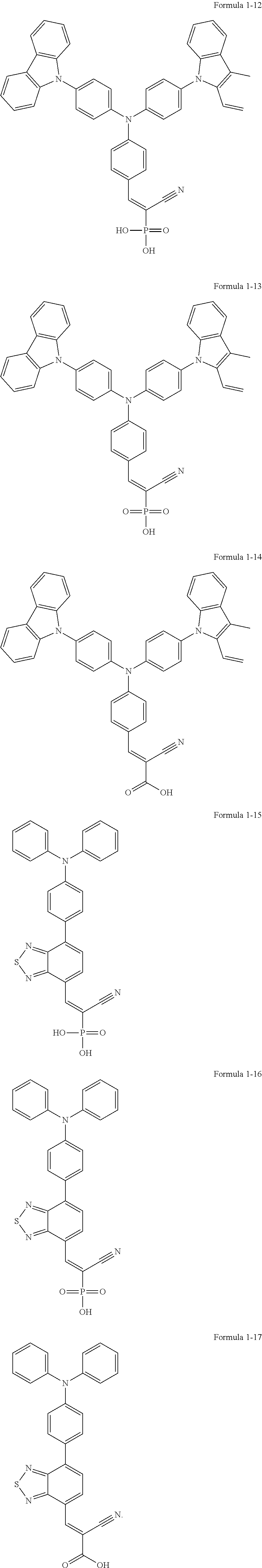

The transport functional materials having the structures represented by Formulas 1-1 to 1-17 have low process temperatures (not more than 100 °C) for preparing the transport layer, and have simple structures. The perovskite precursor solutions containing the transport functional materials are adopted in preparing perovskite solar cells, and the transport functional materials can simultaneously realize passivation of the perovskite layer and bonding to the substrate transparent electrode. As a result, the prepared film layers have improved uniformity and reduced defects.

In some embodiments, the transport functional material is

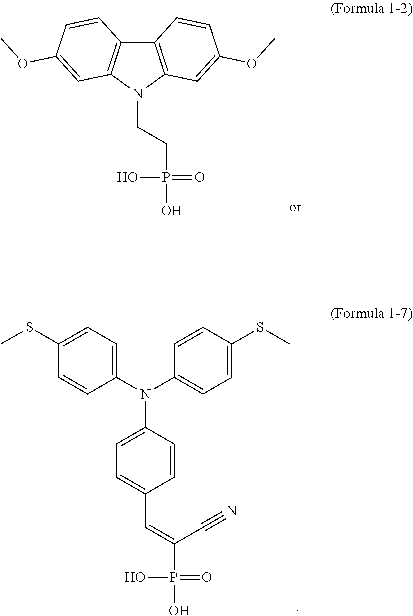

In some embodiments, the synthesis route of the transport functional material (abbreviated as 2,7-MeO-2PACz) represented by Formula 1-2 is as follows.

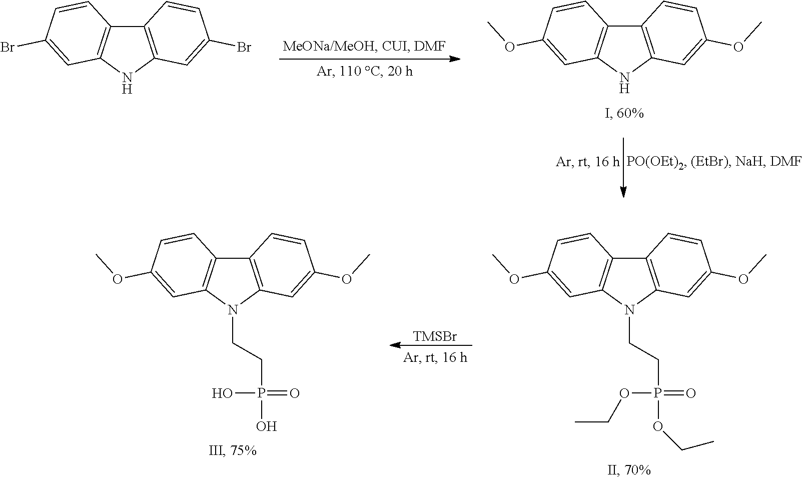

The steps of a specific synthesis process were as follows: 2,7-dibromocarbazole (2.0 g, 6.2 mmol), cuprous iodide (4.7 g, 24.8 mmol), DMF (20 mL), and sodium methoxide/methanol solution (5.0 M, 32 mL) were introduced into a three-neck flask under argon protection, and refluxed at 110 °C for 20 h. The system was cooled to room temperature, filtered through diatomaceous earth, and then concentrated by rotary evaporation. The concentrate was purified by column chromatography with dichloromethane as a mobile phase to obtain 900 mg of pale pink solid intermediate (I) with a yield of 60%. The intermediate (I) (500 mg, 2.2 mmol), sodium hydride (132 mg, 3.3 mmol), and DMF (15 mL) were introduced to a two-neck flask under argon protection. Diethyl(2-bromoethyl)phosphonate (0.5 mL, 2.6 mmol) was added dropwise slowly thereto in an ice bath, and the resulting mixture was stirred overnight at room temperature allowing the ice to melt naturally. The reaction was quenched with ice water, extracted with ethyl acetate, dried with anhydrous sodium sulfate, filtered by suction, and subjected to rotary evaporation to obtain a crude product in an oil form. The crude product was purified by column chromatography with equal proportion of ethyl acetate and n-hexane as a mobile phase, obtaining 600 mg of transparent crystalline intermediate (II) with a yield of 70%. The intermediate (II) (500 mg, 1.3 mmol) and dioxane (15 mL) were introduced into a two-neck flask under argon protection, and then 1.7 mL of bromotrimethylsilane (13 mmol) was slowly added dropwise thereto. The mixture was stirred overnight at room temperature and subjected to rotary evaporation, and the crude product obtained after the rotary evaporation was redissolved in 10 mL of methanol, and then 40 mL of deionized water was added dropwise thereto to obtain 320 mg of pale blue solid product (III) with a yield of 75%.

1H NMR (400 MHz, DMSO-d6): δ 7.87 (d, 2H), 7.03 (d, 2H), 6.77 (dd, 2H), 4.48-4.42 (m, 2H), 2.05-1.97 (m, 2H).

In some embodiments, the synthesis route of the transport functional material (abbreviated as TMPA-CPA) represented by Formula 1-7 is as follows.

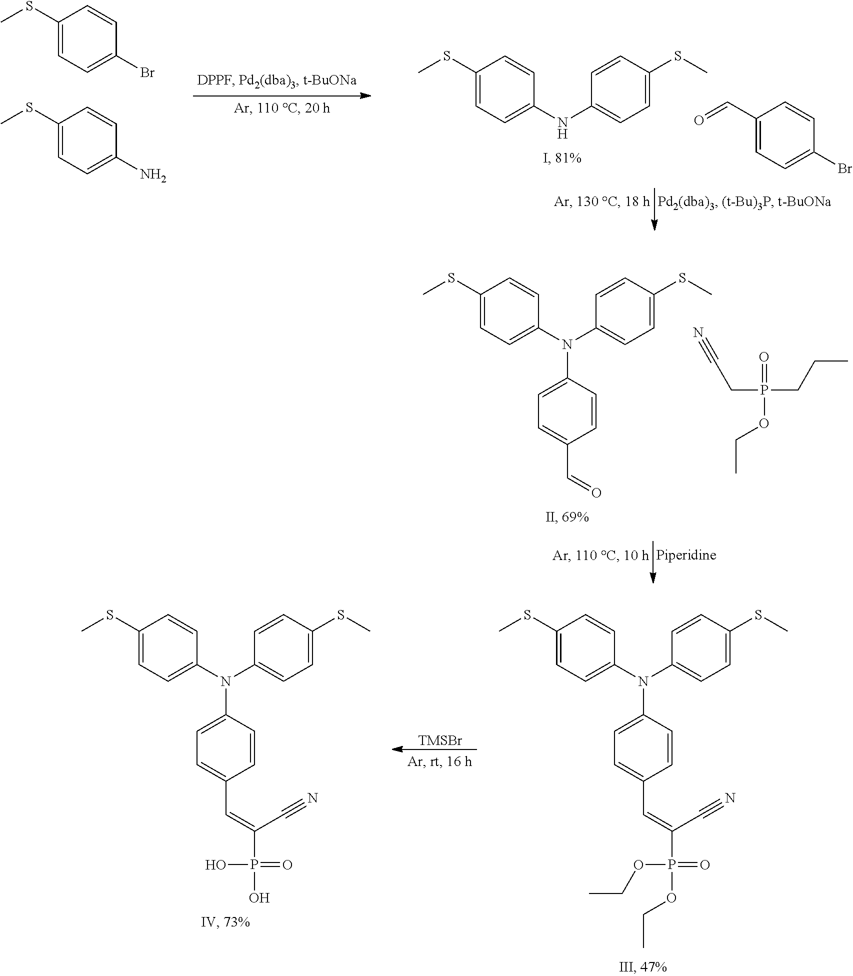

The steps of a specific synthesis process were as follows: 4-bromothioanisole (1.07 g, 5.28 mmol), 4-aminothioanisole (0.88 g, 6.32 mmol), 1,1′-bis(diphenylphosphino) ferrocene (0.349 g 0.63 mmol), tris(dibenzylideneacetone) dipalladium (0.048 g, 0.053 mmol), and sodium tert-butoxide (0.697 g, 7.25 mmol) were introduced into a three-neck flask. The system was purged with argon followed by addition of 15 mL of anhydrous 1,4-dioxane, and then the mixture was refluxed at 110 °C for 20 h. When the reaction was finished, the reaction liquid was extracted with ethyl acetate, and the organic phase was dried with anhydrous sodium sulfate, filtered by suction, and subjected to rotary evaporation to obtain a crude product. The crude product was purified by column chromatography with petroleum ether and ethyl acetate (v:v=30:1) as an eluent to obtain 0.83 g of pale yellow solid intermediate (I) with a yield of 61%. The intermediate (I) (0.80 g, 3.1 mmol), p-bromobenzaldehyde (0.85 g, 4.6 mmol), tris(dibenzylideneacetone) dipalladium (0.028 g, 0.031 mmol), tri-tert-butylphosphine (0.025 g, 0.122 mmol) and sodium tert-butoxide (0.44 g, 4.6 mmol) were introduced into a three-neck flask. The system was purged with argon followed by addition of 15 mL of anhydrous toluene, and then the mixture was refluxed at 130 °C for 18 h. When the reaction was finished, the reaction mixture was filtered through diatomaceous earth, and subjected to rotary evaporation to obtain a reddish-brown crude product in an oil form. The reddish-brown crude product was purified by column chromatography with petroleum ether and ethyl acetate (v:v=3:1) as an eluent to obtain 0.56 g of pale orange solid intermediate (II) with a yield of 69%. The intermediate (II) (0.50 g, 1.35 mmol) was introduced into a two-neck flask. The system was purged with argon, followed by addition of anhydrous toluene (20 mL), diethyl cyanomethylphosphonate (0.5 mL, 3.1 mmol), and piperidine (0.5 mL, 5.1 mmol), and then the mixture was refluxed at 110 °C for 10 h. When the reaction was finished, the reaction mixture was directly subjected to rotary evaporation. The crude product was redissolved in dichloromethane, washed with water, dried with sodium sulfate, filtered by suction, subjected to rotary evaporation, and then purified by column chromatography with dichloromethane and methanol (v:v=10:1) as an eluent, obtaining 0.24 g of orange solid intermediate (III) with a yield of 47%. The intermediate (III) (0.20 g) was introduced to a two-neck flask. The system was purged with argon, followed by addition of dichloromethane (20 mL) and bromotrimethylsilane (0.5 mL), and the mixture was stirred at room temperature overnight. When the reaction was finished, 10 mL of methanol was added, and the mixture was stirred for a while, and then subjected to rotary evaporation to remove the solvent, obtaining 0.20 g of reddish-brown solid product (IV) with a yield of 73%.

1H NMR (400 MHz, DMSO-d6): δ 7.85 (d, 2H), 7.73 (d, 2H), 7.25 (d, 4H), 7.08 (d, 4H), 6.83 (d, 2H), 2.44 (s, 6H).

In some embodiments, the perovskite material includes a perovskite-type metal halide represented by a general formula of ABX₃, where A is a monovalent cation, B is a divalent cation, and X is a monovalent anion.

In some embodiments, A includes Cs⁺, K⁺, Rb⁺, a monovalent amine cation, a monovalent amidinium cation, or any combination thereof. Non-limiting examples of the monovalent amine cation, for example, are CH₃NH₃⁺ (methylammonium, MA⁺), ammonium (NH₄⁺). A non-limiting example of the monovalent amidinium cation, for example, is NH₂CH═NH₂+ (formamidinium, which can be denoted as FA⁺).

In some embodiments, B includes Pb²⁺, Sn²⁺, Fe²⁺, Mn²⁺, Ni²⁺, Ge²⁺, Co²⁺, Sb²⁺, or any combination thereof.

In some embodiments, X includes I⁻, Br⁻, Cl⁻, or any combination thereof.

In some embodiments, X includes one or both of I⁻, Br⁻, X can be I⁻, Br⁻, or a combination thereof. In some embodiments, X is I⁻.

In some embodiments, the perovskite precursor solution further includes an organic solvent. In some embodiments, the organic solvent is selected from the group consisting of N-methylpyrrolidone (NMP), dimethylacetamide (DMAC), acetonitrile (ACN), gamma-butyrolactone (GBL), 2-mercaptoethanol (2-Me), isopropanol (IPA), N, N-dimethylformamide (DMF), dimethyl sulfoxide (DMSO), and any combination thereof. In some embodiments, the organic solvent includes DMF and DMSO in a volume ratio of 4: 1.

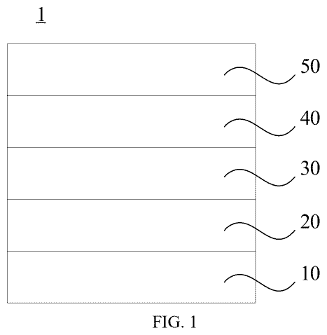

Another embodiment of the present disclosure further provides a method for preparing a perovskite solar cell 1. Referring to FIG. 1, the perovskite solar cell 1 includes a transparent electrode 10, a first transport layer 20, a perovskite layer 30, a second transport layer 40, and a metal electrode 50 that are stacked.

The first transport layer 20 and the second transport layer 40 are configured to transport electrons and holes, respectively. In some embodiments, the first transport layer 20 is an electron transport layer, and the second transport layer 40 is a hole transport layer. In some other embodiments, the first transport layer 20 is a hole transport layer, and the second transport layer 40 is an electron transport layer. The electron transport layer can extract and transport electron carriers, and block the transport of free holes. The hole transport layer can extract and transport hole carriers, and block the transport of free electrons.

The transparent electrode 10 and the metal electrode 50 are two electrodes of the perovskite solar cell 1. One of the two electrodes serves as a positive electrode and can collect electron carriers transported via the electron transport layer. The other electrode serves as a negative electrode and can collect hole carriers transported via the hole transport layer.

The transparent electrode 10 is one electrode of the perovskite solar cell 1 and is configured for light incidence. In some embodiments, the transparent electrode 10 contains fluorine-doped tin oxide (FTO), tin-doped indium oxide (ITO), aluminum-doped zinc oxide (AZO), boron-doped zinc oxide (BZO), indium zinc oxide (IZO), tungsten-doped indium oxide (IWO), etc., or any combination thereof.

The metal electrode 50 is another electrode of the perovskite solar cell 1. Optionally, the metal electrode 50 can be made of an electrically conductive metallic material. In some embodiments, the electrically conductive metallic material can include gold (Au), silver (Ag), copper (Cu), aluminum (Al), nickel (Ni), chromium (Cr), bismuth (Bi), platinum (Pt), magnesium (Mg), etc., or any suitable mixture thereof.

The perovskite layer 30 is a light absorbing layer of the perovskite solar cell 1. The perovskite layer 30 contains the perovskite material. In some embodiments, the perovskite material includes a perovskite-type metal halide represented by a chemical formula of ABX₃, where A is a monovalent cation, B is a divalent cation, and X is a monovalent anion.

In some embodiments, A includes Cs⁺, K⁺, Rb⁺, a monovalent amine cation, a monovalent amidinium cation, or any combination thereof. Non-limiting examples of the monovalent amine cation are CHaNH3+ (methylammonium, MA⁺), ammonium (NH₄⁺). A non-limiting example of the monovalent amidinium cation is NH₂CH═NH₂⁺ (formamidinium, which can be denoted as FA⁺).

In some embodiments, B includes Pb²⁺, Sn²⁺, Fe²⁺, Mn²⁺, Ni²⁺, Ge²⁺, Co²⁺, Sb²⁺, or any combination thereof.

In some embodiments, X includes I⁻, Br⁻, Cl⁻, or any combination thereof.

In some embodiments, X includes one or both of I⁻, Br⁻, X can be I⁻, Br⁻, or a combination thereof. In some embodiments, X is I⁻.

In some embodiments, the method for preparing the perovskite solar cell 1 includes the following steps S100, S200, and S300:

Step S100: The perovskite precursor solution as described above is coated on a surface of the transparent electrode 10 to obtain a wet film.

In some embodiments, the coating is slot-die coating, blade coating, or printing. Optionally, the coating is the slot-die coating. The working principle of the slot-die coating involves that the coating liquid is extruded and sprayed through a slot of a coating die at a certain flow rate under a certain pressure and thereby transferred to a substrate. Compared with other coating methods, the slot-die coating has many advantages, such as high coating speed, high precision, and uniform thickness of the wet film, as well as a high utilization rate of the slurry. The slot-die coating can maintain stable properties of the slurry, and is suitable for multi-layer coating.

Step 200: A solvent is removed from the wet film to obtain a dry film. In some embodiments, the solvent can be removed by vacuum-flash assisted crystallization or air-knife assisted crystallization.

Step 300; The dry film is subjected to annealing treatment to obtain the first transport layer 20 and the perovskite layer 30. In the annealing treatment step, the transport functional material and the perovskite material in the dry film are crystallized and deposited respectively to form the first transport layer 20 and the perovskite layer 30 sequentially on the transparent electrode 10.

In some embodiments, the annealing treatment is conducted at a temperature ranging from 100 °C to 130 °C. The annealing treatment is conducted for 20 minutes to 40 minutes.

The above preparation method involves one-step coating of the perovskite precursor solution provided in the above embodiments of the present disclosure to prepare the first transport layer 20 and the perovskite layer 30, simplifying the process flow compared with the conventional preparation involving step-by-step coating, and avoiding the issue caused by wettability at the solid-liquid interface in the step-by-step coating preparation. During the preparation process, the transport functional material is bonded to the transparent electrode 10 on the one hand, and passivates the defects of the perovskite layer 30 on the other hand, allowing the first transport layer 20 and the perovskite layer 30 to have improved morphology and performances. Compared with the conventional preparation process, the above preparation method simplifies the process flow, and improves the morphology and performances of the prepared film layer, which is conducive to improving the photoelectric performance of the perovskite solar cell 1, and is especially suitable for large-scale and large-area industrial production of the perovskite solar cell 1.

In some embodiments, the method for preparing the perovskite solar cell 1 further includes steps S400 and S500:

Step S400: A second transport layer 40 is prepared on a surface of the perovskite layer 30.

Step S500: A metal electrode 50 is prepared on a surface of the second transport layer 40

Another embodiment of the present disclosure provides a perovskite solar cell 1 prepared by the method for preparing the perovskite solar cell 1 as described above.

Another embodiment of the present disclosure provides a photovoltaic system including the perovskite solar cell 1 as described above.

The photovoltaic system can be applied to photovoltaic power stations, such as ground power stations, roof power stations, water surface power stations, etc., and can be applied to equipment or devices that use solar energy to generate electricity, such as user solar power supplies, solar street lights, solar cars, solar buildings, etc. It can be understood that the application scenarios of the photovoltaic system are not limited to the above, in other words, the photovoltaic system can be applied in all fields that need to use solar energy to generate electricity. Taking a photovoltaic power generation network as an example, the photovoltaic system can include a photovoltaic array, a combiner box, and an inverter. The photovoltaic arrays can be a combination of arrays of multiple perovskite solar cells 1. For example, the multiple perovskite solar cells 1 can form a plurality of photovoltaic arrays. The photovoltaic arrays are connected to the combiner box, which can combine the electrical currents generated by the photovoltaic arrays. The combined electrical current flows through the inverter and is converted into the alternating current suitable for the urban power grid, and then connected to the urban power grid to realize solar power supply.

The following are specific examples.

### Example 1

The method for preparing a perovskite solar cell of this example included the following steps:

(1) Preparation of a perovskite precursor solution: A perovskite material and a transport functional material TMPA-CPA were dissolved in a solvent of DMF:DMSO=4:1 (volume ratio) by stirring at 25 °C overnight, where the concentration of the perovskite material was 1.5 M, and the concentration of the transport functional material TMPA-CPA was 0.5 mg/mL.

(2) A 10×10 cm² ITO-coated glass plate with a thickness of 1.1 mm and a sheet resistance of about 20 Ω/m² was taken as a substrate. The substrate was ultrasonically cleaned with surfactant, deionized water, acetone, and isopropanol each for 20 minutes in sequence, and then soaked in isopropanol for later use. The cleaned substrate was treated with a plasma cleaner for 20 minutes.

(3) The perovskite precursor solution obtained in step (1) was injected into a slot-die coating machine, and coated on the surface of the substrate to obtain a wet film. The wet film was subjected to air-knife assisted crystallization to remove the organic solvent, and then was subjected to annealing treatment at 120 °C for 30 minutes to grow perovskite crystals and a first transport layer, thereby obtaining a first transport layer and a perovskite layer.

(4) At a vacuum degree of 1×10⁻⁴ Pa, a C60 layer (25 nm) as an electron transport layer and a BCP layer (6 nm) as a buffer modification layer were sequentially evaporated and deposited, and then 100 nm Ag was deposited as a top metal electrode.

(5) The device prepared in step (4) was encapsulated with butyl sealant to obtain the perovskite solar cell of this example.

### Comparative Example 1

The method for preparing a perovskite solar cell of this comparative example included the following steps:

(1) Preparation of a perovskite precursor solution and a hole transport material solution: A perovskite material was dissolved in a solvent of DMF:DMSO=4:1 (volume ratio) by stirring at 25 °C overnight to prepare a perovskite precursor solution with a concentration of 1.5 M. The transport functional material TMPA-CPA was dissolved in methanol to prepare a hole transport material solution with a concentration of 0.5 mg/mL.

(2) A 10×10 cm² ITO-coated glass plate with a thickness of 1.1 mm and a sheet resistance of about 20 (Ω/m² was taken as a substrate. The substrate was ultrasonically cleaned with surfactant, deionized water, acetone, and isopropanol each for 20 minutes in sequence, and then soaked in isopropanol for later use. The cleaned substrate was treated with a plasma cleaner for 20 minutes.

(3) The hole transport material solution obtained in step (1) was injected into a slot-die coating machine, and coated on the surface of the substrate to obtain a wet film. The wet film was subjected to annealing treatment at 120 °C for 10 minutes to grow a hole transport layer which was bonded to ITO.

(4) The perovskite precursor solution obtained in step (1) was injected into a slot-die coating machine, and then was coated on the surface of the hole transport layer to obtain a wet film. The wet film was subjected to air-knife assisted crystallization to remove the organic solvent, and then was subjected to annealing treatment at 120 °C for 30 minutes to grow perovskite crystals, thereby obtaining a perovskite layer.

(5) At a vacuum degree of 1×10⁻⁴ Pa, a C60 layer (25 nm) as an electron transport layer and a BCP layer (6 nm) as a buffer modification layer were sequentially evaporated and deposited, and then 100 nm Ag was deposited as a top metal electrode.

(6) The device prepared in step (5) was encapsulated with butyl sealant to obtain the perovskite solar cell of this comparative example.

Testing: J-V characteristics of the devices under AM1.5 G (100 mWcm⁻²) were measured using a solar simulator (a xenon lamp with an AM1.5 G filter) in air at room temperature. A standard Si diode with a KGS filter was purchased from and calibrated by National PV Industry Measurement and Testing Center of Fujian Metrology Institute. The light intensity was calibrated using the Si cell. The reference cell brought spectral mismatch to unity. The J-V characteristics were recorded using a Keithley 2400 source meter unit.

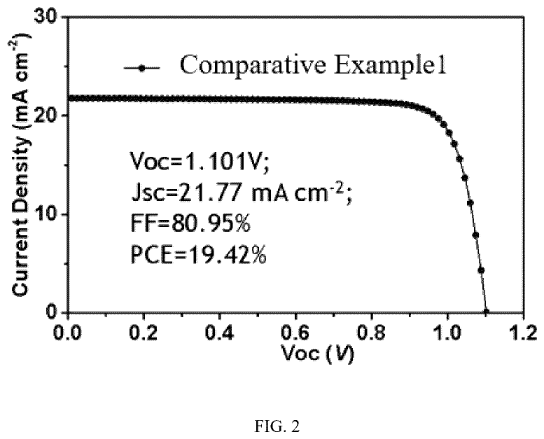

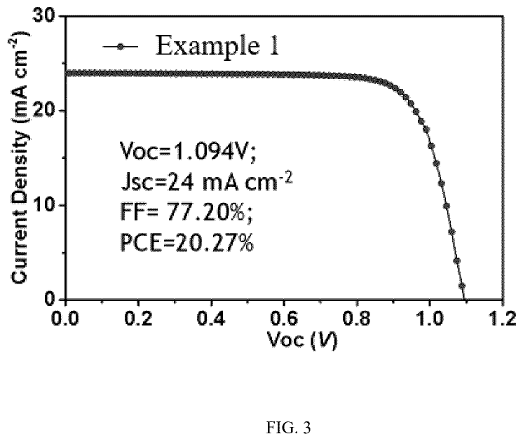

FIGS. 2 and 3 are referred, which show J-V curves of perovskite solar cells prepared in Comparative Example 1 and Example 1, respectively. As can be seen from the figures, the photoelectric conversion efficiency of the perovskite solar cell prepared in Comparative Example 1 is 19.42%, and the photoelectric conversion efficiency of the perovskite solar cell prepared in Example 1 is 20.27%, indicating that the perovskite solar cell including the first transport layer and the perovskite layer, which were prepared by one-step coating of the perovskite precursor solution provided by the embodiments of the present disclosure, has a better photoelectric conversion performance.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, which is convenient for a specific and detailed understanding of the technical solutions of the present disclosure, but should not be construed as limiting the scope of the present disclosure. It should be understood by those of ordinary skill in the art that various modifications and improvements can be made without departing from the concept of the present disclosure, and all fall within the protection scope of the present disclosure. It should also be understood that the technical solutions obtained by those of ordinary skill in the art through logical analysis, reasoning, or limited experiments based on the technical solutions provided by the present disclosure are within the scope of the appended claims of the present disclosure. Therefore, the protection scope of the present disclosure shall be defined by the appended claims, and the specification and drawings can be used to explain the contents of the claims.

1. A perovskite precursor solution, comprising a perovskite material and a transport functional material, wherein the transport functional material has a structure shown in Formula I: 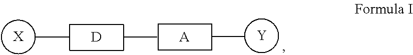
where A represents an electron acceptor, D represents an electron donor, X represents a donor group, and Y represents an acceptor group.

2. The perovskite precursor solution according to claim 1, wherein A is selected from the group consisting of 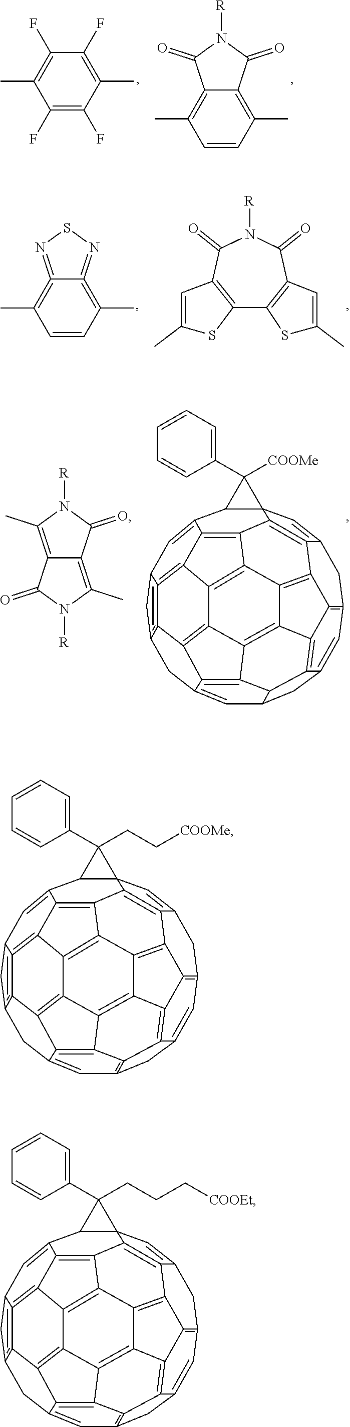 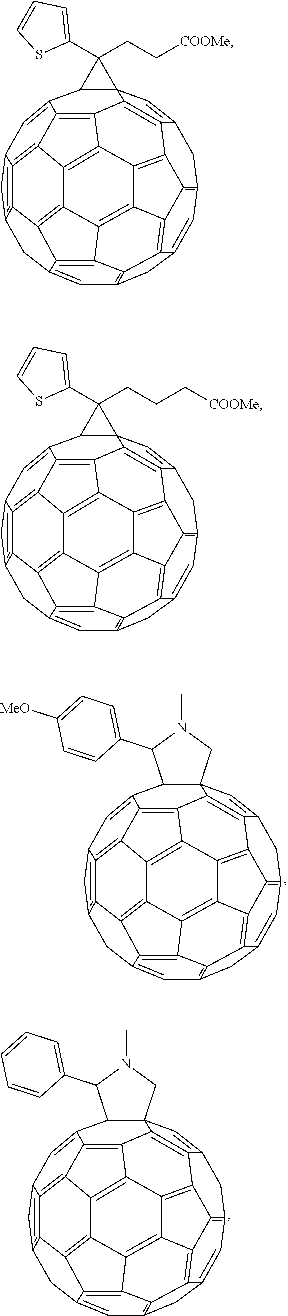 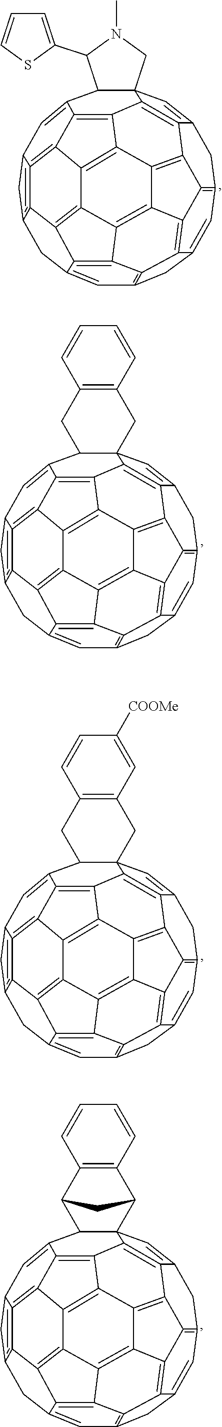 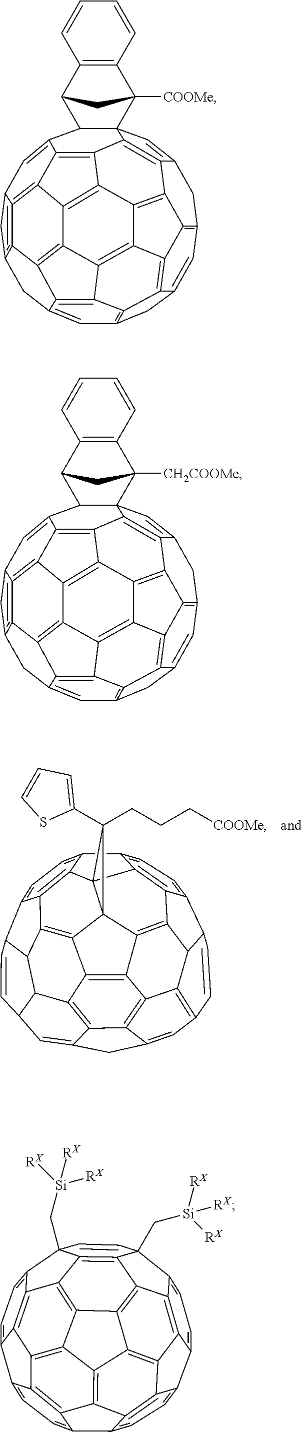
D is selected from the group consisting of 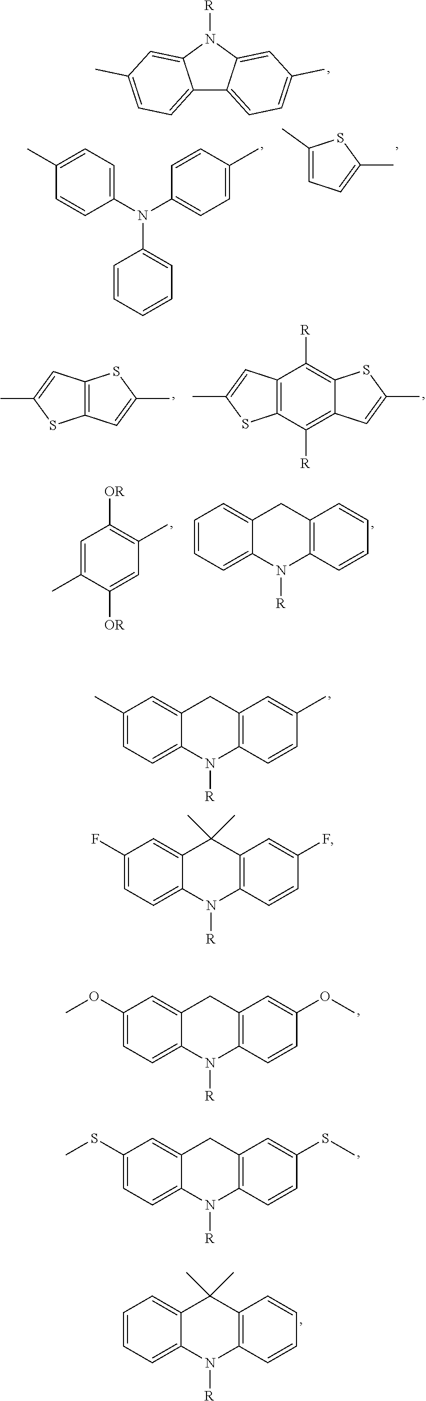 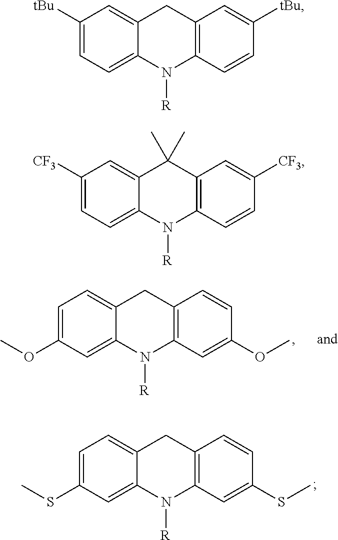
X is selected from the group consisting of 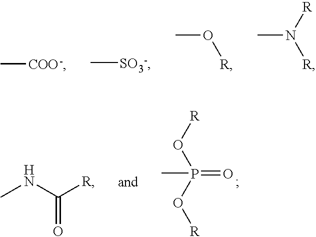
and
Y is selected from the group consisting of 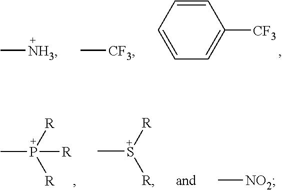
wherein R and R^{X} are each independently selected from the group consisting of linear alkyl, branched alkyl and cyclic alkyl each having 2 to 40 carbon atoms, where one or more non-adjacent carbon atoms are optionally substituted by —O—, —S—, —C(O)—, —C(O—)—O—, —O—C(O)—, —O—C(O)—O—, —CR⁰—CR⁰⁰—, or —C═C—, and one or more hydrogen atoms are unsubstituted or substituted by F, Cl, Br, I, or CN; or R and R^{X} each independently represent aryl, heteroaryl, aryloxy, heteroaryloxy, arylcarbonyl, heteroarylcarbonyl, arylcarbonyloxy, heteroarylcarbonyloxy, aryloxycarbonyl or heteroaryloxycarbonyl, each having 4 to 30 ring atoms unsubstituted or substituted by one or more non-aromatic groups;
wherein R⁰ and R⁰⁰ are each independently linear alkyl, branched alkyl, or cyclic alkyl.

3. The perovskite precursor solution according to claim 1, wherein the transport functional material is selected from the group consisting of

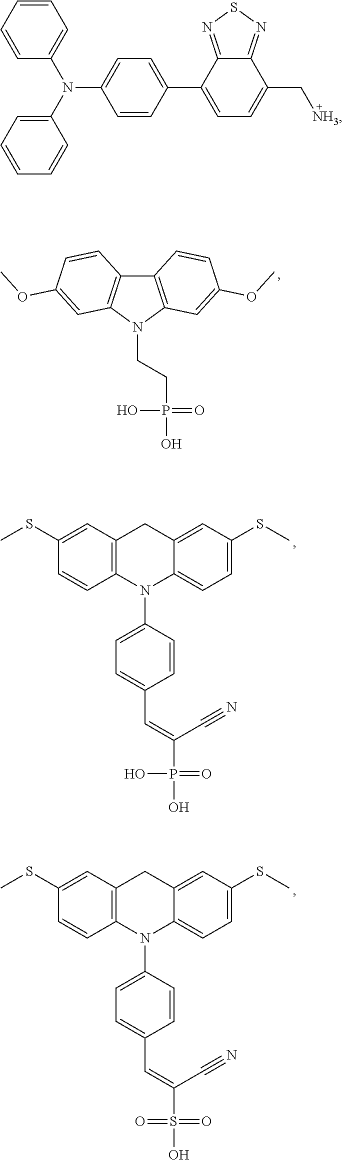

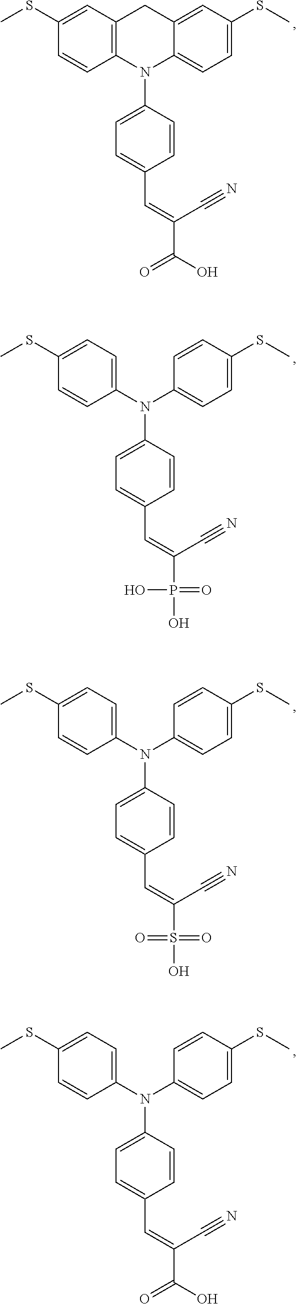

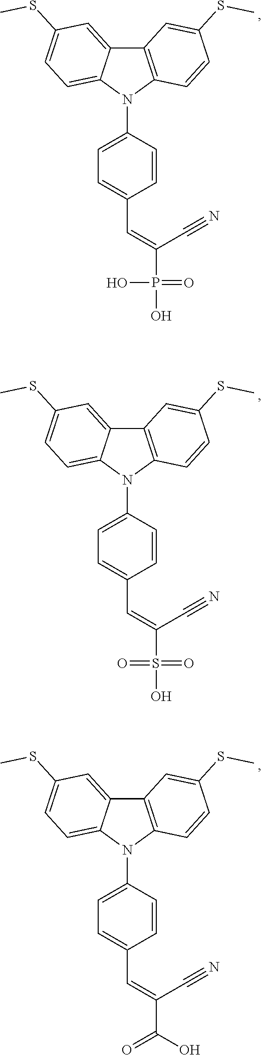

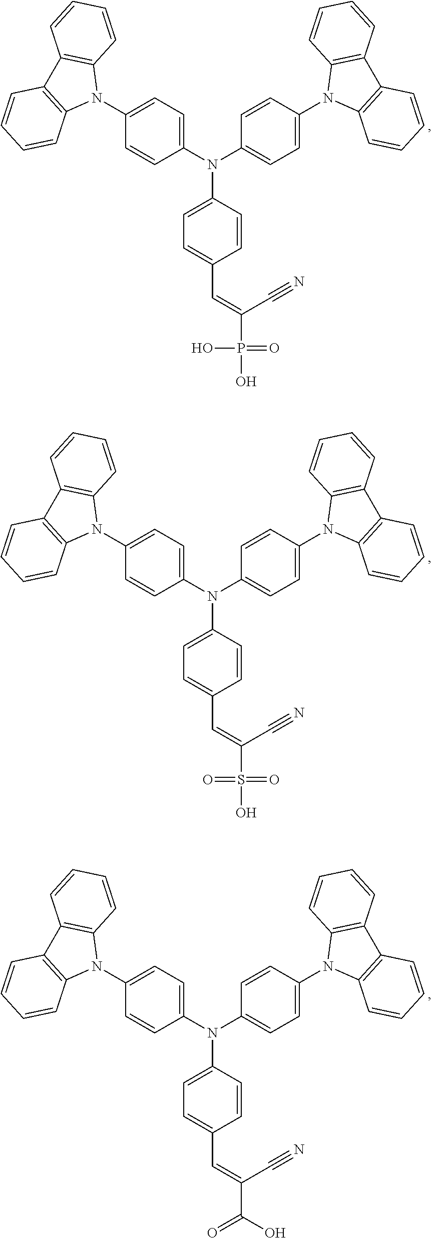 [SMILES: N#C/C(=C\c1ccc(N(c2ccc(-n3c4ccccc4c4ccccc43)cc2)c2ccc(-n3c4ccccc4c4ccccc43)cc2)cc1)P(=O)(O)O ; N#C/C(=C\c1ccc(N(c2ccc(-n3c4ccccc4c4ccccc43)cc2)c2ccc(-n3c4ccccc4c4ccccc43)cc2)cc1)S(=O)(=O)O ; N#C/C(=C\c1ccc(N(c2ccc(-n3c4ccccc4c4ccccc43)cc2)c2ccc(-n3c4ccccc4c4ccccc43)cc2)cc1)C(=O)O]

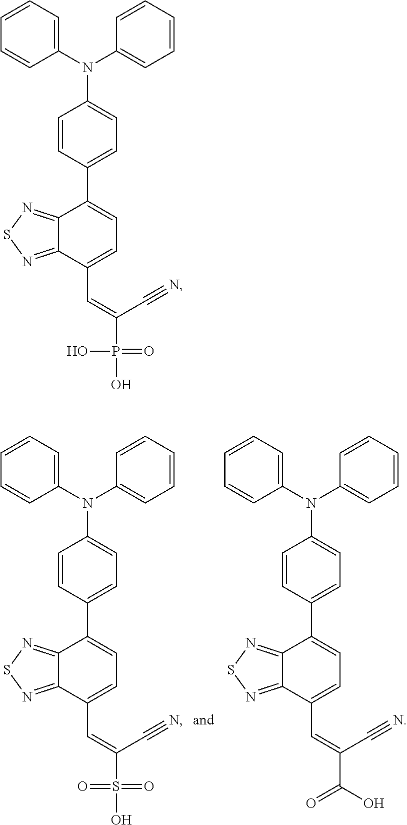 [SMILES: N#C/C(=C\c1ccc(-c2ccc(N(c3ccccc3)c3ccccc3)cc2)c2nsnc12)P(=O)(O)O ; N#C/C(=C\c1ccc(-c2ccc(N(c3ccccc3)c3ccccc3)cc2)c2nsnc12)S(=O)(=O)O ; "and" ; N#C/C(=C\c1ccc(-c2ccc(N(c3ccccc3)c3ccccc3)cc2)c2nsnc12)C(=O)O]

4. The perovskite precursor solution according to claim 1, wherein the transport functional material is

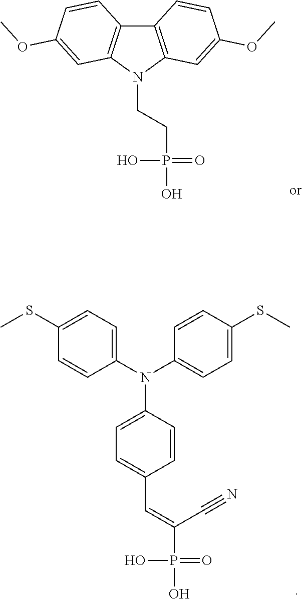

5. The perovskite precursor solution according to claim 1, wherein the perovskite material comprises a perovskite-type metal halide represented by a general formula of ABX₃, where A is a monovalent cation, B is a divalent cation, and X is a monovalent anion.

6. A method for preparing a perovskite solar cell, wherein the perovskite solar cell comprises a transparent electrode, a first transport layer, a perovskite layer, a second transport layer, and a metal electrode that are stacked;
the method for preparing the perovskite solar cell comprises steps of:
coating the perovskite precursor solution according to claim 1 on a surface of the transparent electrode to obtain a wet film;
removing a solvent from the wet film to obtain a dry film; and
subjecting the dry film to annealing treatment to obtain the first transport layer and the perovskite layer.

7. The method according to claim 6, wherein the coating is slot-die coating, blade coating, or printing;
optionally, the coating is slot coating.

8. The method according to claim 6, further comprising:
preparing the second transport layer on a surface of the perovskite layer; and
preparing the metal electrode on a surface of the second transport layer.

9. A perovskite solar cell prepared by the method according to claim 6.

10. A photovoltaic system, comprising the perovskite solar cell according to claim 9.
